(19) United States
(12) Patent Application Publication
(10) Pub. No.: US 2008/0224570 A1
(43) Pub. Date: Sep. 18, 2008

(54) Transformer Arrangement Having a Piezoelectric Transformer

(75) Inventors: Heinz Florian, Bad Gams (AT); Alexander Glazunov, Deutschlandsberg (AT); Igor Kartashev, Deutschlandsberg (AT)

Correspondence Address: FISH & RICHARDSON PC, P.O. BOX 1022, MINNEAPOLIS, MN, 55440-1022, US

(73) Assignee: EPCOS AG, Munich (DE)

(21) Appl. No.: 11/997,420

(22) PCT Filed: Jul. 27, 2006
(86) PCT No.: PCT/DE2006/001302

§ 371 Date: Mar. 25, 2008

(30) Foreign Application Priority Data
Aug. 1, 2005 (DE) 102005036077.7

(51) Int. Cl. H01L 41/053; H01L 41/107

(52) U.S. Cl. 310/341

(57) ABSTRACT

A transformer arrangement is specified which includes a piezoelectric transformer with a main body (1), and a cooling body (7) on which the main body (1) is arranged, wherein the main body (1) is thermally coupled to the cooling body (7) by means of at least one heat-conducting coupling element (8).

A piezoelectric transformer is suitable for transforming a high voltage to a low voltage or vice versa.

Piezoelectric transformers are known, e.g., from publication U.S. Pat. No. 2,830,274.

A problem to be solved is to specify an arrangement with a piezoelectric transformer, which is especially reliable and has a long service life.

A transformer arrangement is specified, which includes a piezoelectric transformer with a main body, and a cooling body on which the main body is arranged. The main body is thermally coupled to the cooling body by means of at least one heat-conducting coupling element.

A heat-conducting coupling element guarantees good heat contact between the main body and the cooling body and therefore also good heat exchange. Thus, the heat produced in the main body can be dissipated from the main body. This is advantageous especially for piezoelectric transformers designed for high powers of greater than 50 W.

Advantageous constructions of the transformer arrangement are explained below.

The main body includes an input part and an output part of the transformer, as well as an insulating region, by means of which the input part and the output part are mechanically connected to each other and galvanically separated from each other.

On the main body surface, preferably outer electrodes are arranged, which are conductively connected in one variant to internal electrodes buried in the main body. The internal electrodes are connected alternately to the first and to the second external electrodes of the corresponding transformer part. An acoustic wave can be excited by applying an electrical alternating voltage to the internal electrodes of the input part. The acoustic wave, however, can also be excited between opposing external electrodes of the input part. The wave excited electrically in the input part by an input signal is transmitted to the output part of the piezoelectric transformer and is converted into an electrical output signal.

The main body preferably has the shape of a right parallelepiped. The main body can also have a different shape, however, e.g., that of a cylinder or a disk.

The cooling body can form at least one part of a housing of the transformer arrangement, in which the main body of the piezoelectric transformer is arranged. The housing can have a U-profile in one direction or in two directions perpendicular to each other. The housing can also have the shape of a cup. In the housing, especially in its side walls, an arbitrary number of ventilation openings can be provided. The cooling body can also form at least one part of a holding device on which the main body is arranged. The holding device can include, e.g., a base plate. In the cooling body, attachment devices or openings or recesses for holding such devices can be arranged. The attachment devices can be provided, e.g., for fixing the main body. By means of the attachment devices, the transformer arrangement can be attached to an external carrier in one variant.

The cooling body can include a cooling plate made from a material with good heat-conducting properties. The cooling body can have, in addition to a base plate, side walls that advantageously form one piece with the base plate or are attached to this plate.

Below, only one heat-conducting coupling element is explained, wherein the description then also applies to other such elements of the same transformer arrangement.

The heat-conducting coupling element is arranged in one variant on the base of the cooling body and represents a support for the main body. Several heat-conducting coupling elements can also be provided, each of which forms a support for the main body. The main body is mounted on the coupling element or the coupling elements and preferably at a distance from the side walls of the cooling body or the housing. The main body can be fixed alternatively by means of at least two coupling elements between the side walls of the cooling body, wherein the main body is preferably at a distance from the base of the cooling body or the housing.

The heat-conducting coupling element also mechanically couples the main body and the cooling body, so that shifts of the main body can be transmitted via this coupling element to the cooling body. For a large-area coupling, the acoustic oscillations of the main body are transmitted via the coupling element to the cooling body, which can lead to losses and decreased efficiency. The contact surface between the one or more heat-conducting coupling elements and the main body is therefore preferably smaller than the surface of the side of the main body contacting this coupling element. The heat-conducting coupling element with a comparatively small contact surface functions as a heat sink. The contact surface between the heat-conducting coupling element and the main body is preferably selected to be large enough that an efficient heat exchange is guaranteed between the main body and the cooling body.

The heat-conducting coupling element can be used as a spacing element for forming an air gap between the main body and the cooling body. In an advantageous variant, at least two heat-conducting coupling elements spaced apart from each other are provided as spacers between the main body and the cooling body. In particular, areas of the main body at which antinodes appear are held at a distance from the cooling body. The length of the air gap measured in the wave propagation direction equals, e.g., at least 50%, in one variant between 60% and 90%, of the length of the main body measured in this direction.

To keep the transmission of oscillations of the main body to the cooling body low, it is advantageous to arrange the coupling elements outside of those regions of the main body surface in which the main body is mostly moved by the acoustic wave. The length of the heat-conducting coupling element is therefore preferably selected so that it is kept away from the regions of the main body in which antinodes of the acoustic wave appear.

The heat-conducting coupling element or elements are each limited preferably essentially to one node region. This is preferably an elongated region of the main body surface, in which nodes of an acoustic wave excited in the main body appear or in which the amplitude of the acoustic oscillations does not exceed a certain level, e.g., 20% of the maximum oscillation amplitude, wherein the maximum oscillation amplitude often appears at the open ends of the main body. A region of the main body, whose length in the wave propagation direction equals a maximum of 20% of the acoustic wavelength λ, is designated as a node region. Outside of the node regions, the main body preferably does not touch the cooling body or is spaced away from this cooling body.

The length of the heat-conducting coupling element measured in the wave propagation direction of the acoustic wave excited in the main body is preferably less than the length of the main body measured in this direction. The length of the coupling element equals, e.g., a maximum of 30%, preferably a maximum of 20%, in one variant a maximum of 10%, of the length of the main body measured in this direction.

The heat-conducting coupling element can extend, for example, parallel to a wave front, i.e., in a direction running perpendicular to the wave propagation direction. The heat-conducting coupling element is here preferably elongated.

The total surface area of the cooling body is preferably greater than the total surface area of the main body. The cooling body can have ribs in one variant. This has the advantage of effecting an especially large total surface area of the cooling body.

To keep the transmission of oscillations of the main body to the cooling body low, it is advantageous to select the heat-conducting coupling element from a material in which mechanical oscillations are damped, especially at a resonance frequency of the piezoelectric transformer. This is possible, e.g., if the coupling element is capable of oscillating. Coupling elements made from an elastically deformable or rubber-like material are therefore especially suitable. The heat-conducting coupling element can be, e.g., a heat-conducting paste or a heat-conducting gel.

The heat-conducting coupling element is electrically insulating in another variant. The heat-conducting coupling element is electrically conductive in another variant.

The electrically conductive, heat-conducting coupling element can contact a contact layer arranged on the main body and a contact layer arranged on the cooling body and can connect these contact layers to each other conductively. The contact layer arranged on the main body can be an external electrode of the piezoelectric transformers. The contact surface arranged on the cooling body is preferably connected to a connection of the cooling body accessible from the outside.

Preferably, at least one heat-conducting coupling element is arranged on each opposing side of the main body.

In one embodiment, a heat-conducting coupling element, which thermally couples the main body to the cooling body, is arranged on the bottom side and on the top side of the main body. Here, the wave propagation direction is preferably a lateral direction (longitudinal oscillator). In another embodiment, a heat-conducting element is arranged on opposite sides or side surfaces of the main body. Here, the wave propagation direction is preferably a vertical direction (thickness oscillator).

The lower heat-conducting coupling element arranged between the bottom side of the main body and the cooling body is preferably coupled directly to the cooling body, while the upper heat-conducting coupling element is connected to the cooling body with good thermal conductivity, preferably by means of another element—preferably a spring element explained below. The upper heat-conducting coupling element can have the properties named in connection with the lower heat-conducting coupling element. In one variant, the upper and also the lower heat-conducting coupling element are electrically conductive.

The spring element presses the main body from above against one or more supports, which are preferably formed by the heat-conducting coupling element or elements. Thus, the main body can be reliably fixed on the cooling body or in the housing. A spring tongue or an elastically deformable stopper is suitable as the spring element.

The spring element presses the upper heat-conducting coupling element against the main body and connects them thermally to the cooling body. The spring element can conductively connect the upper heat-conducting coupling element to contact surfaces arranged on the cooling body.

The spring element can be biased, e.g., by means of a spring clip on the cooling body. The spring clip can be guided, e.g., by openings in the cooling body and by means of bends in the cooling body. The distance between these openings is preferably less than the clamping width between the not-yet biased spring clips. The ends of the spring clips pointing downward can be bent, wherein their bent regions press against the cooling body from below.

In the cooling body or on the cooling body, locking devices can be provided for locking the spring element or the spring clip of the spring element.

Between one wall of the cooling body and a side of the main body arranged parallel to the wave front, an intermediate element can be arranged, which 1) is used as a holder of the main body in the cooling body and 2) reduces the transmission of main body vibrations to the cooling body. The intermediate element is suitable for damping mechanical oscillations excited in the main body. Preferably, in the wave propagation direction, two such intermediate elements are provided, wherein an intermediate element is arranged between one wall of the cooling body and the side surface of the main body facing it. The two intermediate elements are arranged, e.g., along one axis, preferably a middle axis of the main body parallel to the wave propagation direction. Because they connect the main body mechanically to the cooling body, they are preferably selected from a material in which mechanical oscillations of the main body are damped. The contact between the intermediate element and the main body is preferably essentially a point contact. In each case, the contact surface between the intermediate element and the main body is smaller in terms of surface area than the side of the main body including this contact surface.

In one variant, the acoustic wave propagates in a longitudinal direction, i.e., parallel to the main surfaces of the main body. The wave propagation direction can be directed in the radial direction in the case of a disk-shaped main body. In this variant, the antinodes appear on end sides of the main body and—for the second harmonic of the piezoelectric transformer—in its relatively narrow middle region running parallel to these end sides. The nodes appear in a narrow main body region, which is arranged in the middle between two antinode regions.

In the main body, a thickness oscillation can be realized in one variant, wherein the wave propagation direction is directed vertical or perpendicular to the bottom side of the main body. In this variant, the antinodes appear on the main surfaces of the main body—or the second harmonic also in its relatively narrow middle region running parallel to these main surfaces. The nodes appear in a narrow main body region, which is arranged in the middle between two antinode regions. The node and antinode regions extend parallel to a lateral plane.

The main body realized as a thickness oscillator can be constructed, e.g., as a disk. In this case, an already mentioned, preferably an oscillation-damping intermediate element is arranged between the base plate of the cooler and the bottom side of the main body. The intermediate element is preferably arranged along a middle axis of the main body parallel to the wave propagation direction between the bottom side of the main body and the base of the cooling body.

For a thickness oscillator, a cup-shaped cooling body is suitable, whose outer surface forms, in one variant, an outer tube—or for a disk-shaped main body, an outer cylinder. For example, a disk-shaped main body can be clamped in the outer tube of the cooling body by means of the preferably elastically deformable coupling elements or can be connected rigidly to this outer tube by means of the coupling elements.

Preferably, in at least one direction or radial direction, at least one heat-conducting coupling element, which thermally couples the main body to the side wall of the cooling body, is arranged on opposite sides of the main body. The main body is held between the side walls of the cooling body mainly by at least two coupling elements.

The main body can have an annular cross section, i.e., an inner and an outer surface or side surface.

In this case, the cooling body can be constructed with an outer tube and an inner tube and optionally a base connecting the outer tube and the inner tube, that is, as a trough with an inner hole. The outer tube and the inner tube here each form a side surface of the cooling body. The outer tube and the inner tube can by cylindrical—especially in the case of an annular main body with a round cross section. However, they can also have a rectangular form—in the case of a closed main body with an inner hole, but a rectangular form.

Between the outer surface of the main body and the inside of the outer tube, a heat-conducting coupling element can be arranged in at least one radial direction—preferably on opposite sides of the main body. Furthermore, another heat-conducting coupling element can be arranged in at least one radial direction—preferably also on opposite sides of the main body—between the inner surface of the main body and the inner tube of the cooling body.

The annular main body is then clamped according to the embodiment between the inner tube and the outer tube of the cooling body by means of the preferably elastically deformable coupling element or rigidly connected to the side surfaces of the cooling body by means of the coupling element.

The cooling body can contain, in one variant, an electrically insulating material with good thermal conductivity. The cooling body can contain, e.g., a ceramic material with good thermal conductivity. As a ceramic, in particular PZT (lead zirconate titanate) is suitable. On the surface of the electrically insulating cooling body there can be connections constructed as contact surfaces.

An electrically insulating cooling body can also contain an electrically conductive core element, preferably a metal main body, which is covered with an insulating layer, e.g., made from glass or an oxide.

However, the cooling body can also include a metal main body, e.g., a metal plate. In the cooling body, openings are then preferably formed, in each of which an electrically insulating insert is arranged, in which a pin-shaped electrical connection is held.

The electrical connection of the cooling body is preferably conductively connected by means of a wire connection to an external electrode arranged on the surface of the main body.

The wire connection is preferably shaped such that it damps the transmission of mechanical oscillations of the main body to the cooling body, especially at a resonance frequency of the piezoelectric transformer.

The length of the wire connection is preferably greater than the distance between the external electrode and the connection of the cooling body. The wire connection can include, e.g., at least one metal layer and at least one plastic layer.

The piezoelectric transformer and the arrangement with a piezoelectric transformer are explained below with reference to schematic figures that are not true to scale. Shown are:

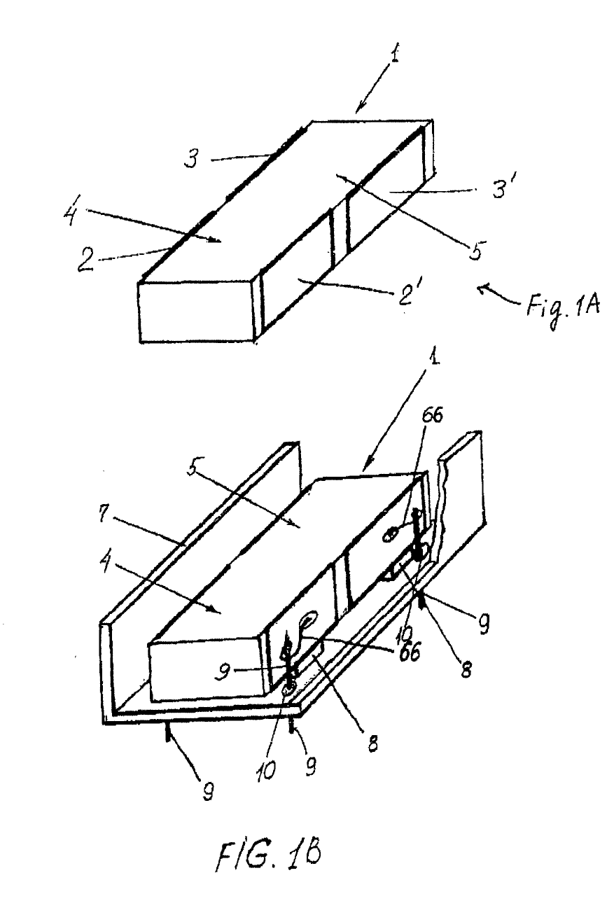

FIG. 1A, a perspective view of a piezoelectric transformer;

FIG. 1B, a perspective view of a transformer arrangement, in which the transformer according to FIG. 1A is thermally coupled to a cooling body by means of a layer with relatively high thermal conductivity;

FIG. 1C, in cross section, the transformer arrangement according to FIG. 1B;

FIG. 1D, a first cross section of another transformer arrangement, in which the main body of a piezoelectric transformer is thermally coupled from below to the base plate of the cooling body and from above to its walls, perpendicular to the longitudinal axis of the main body;

FIG. 1E, a second cross section of the transformer arrangement according to FIG. 1D along the longitudinal axis of the main body;

FIG. 1F, a top view onto the transformer arrangement according to FIGS. 1D and 1E;

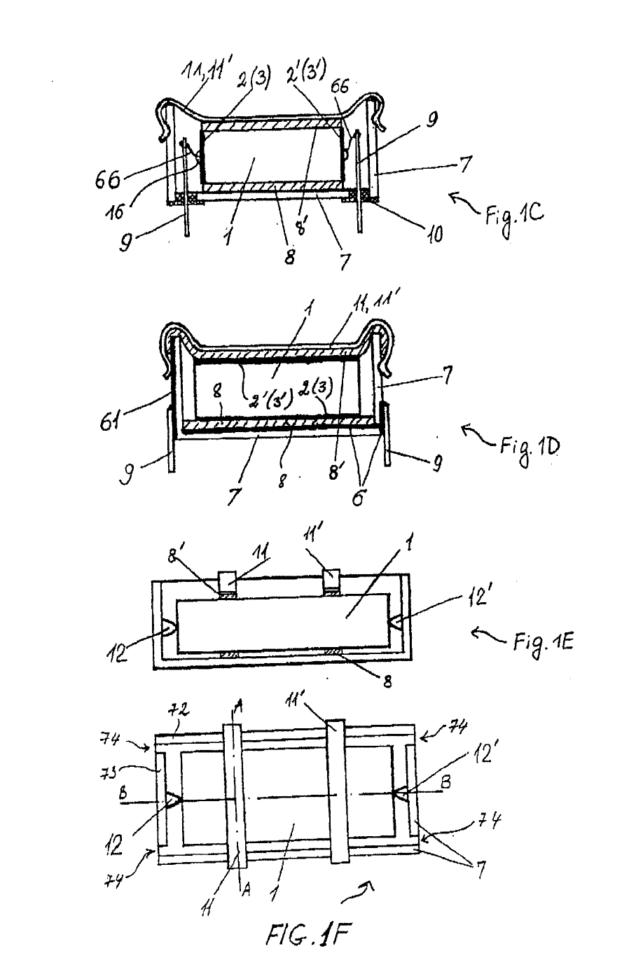

FIG. 2, another transformer arrangement, in which the disk-shaped main body of a piezoelectric transformer is conductively connected by means of wire connections to connections of the cooling body;

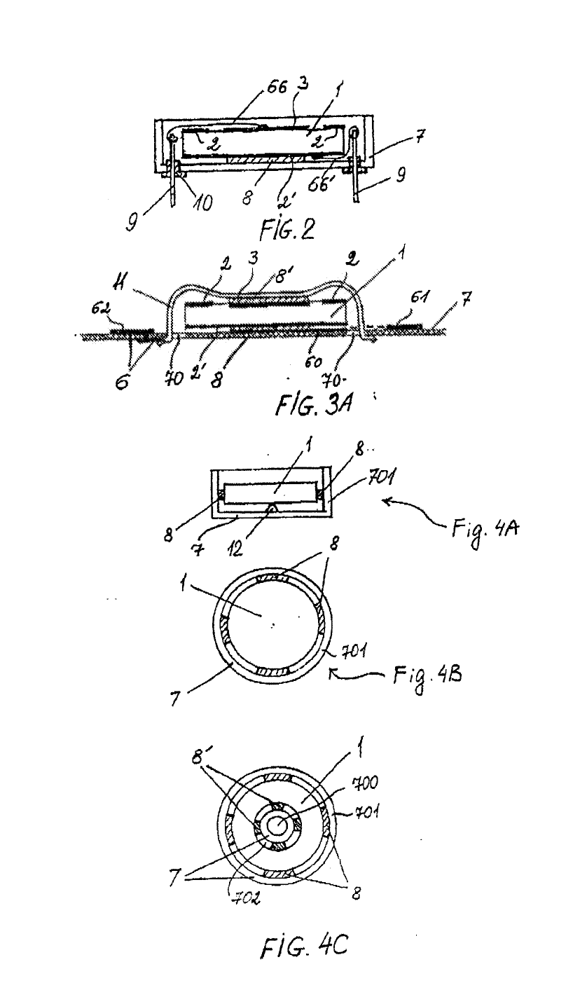

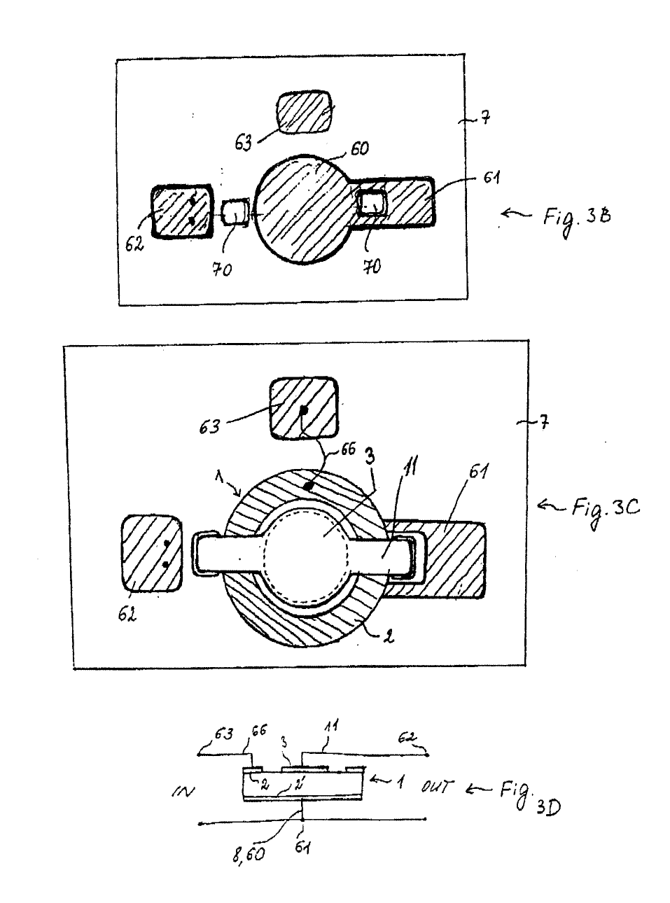

FIG. 3A, a transformer arrangement, in which the disk-shaped main body of a piezoelectric transformer is thermally coupled to a spring element biased in the cooling body by means of an upper layer with relatively high thermal conductivity;

FIG. 3B, a view on the base plate of the cooling body for the transformer arrangement according to FIG. 3A from above;

FIG. 3C, a view on the transformer arrangement according to FIG. 3A with the cooling body according to FIGS. 3A, 3B and the piezoelectric transformer according to FIGS. 3D, 3A from above;

FIG. 3D, the connection sequence of the electrodes of the piezoelectric transformer according to FIG. 3A to the connections of the cooling body;

FIGS. 4A and 4B, different cross sections of a transformer arrangement, in which the disk-shaped main body of a piezoelectric transformer is arranged in a cup-shaped cooling body, wherein the outer surface of the main body is thermally coupled to the walls of the cup;

FIG. 4C, a transformer arrangement, in which the main body of a piezoelectric transformer forms a closed ring, and in which the cooling body is formed as a closed trough, which holds the main body and whose walls are thermally coupled to this main body;

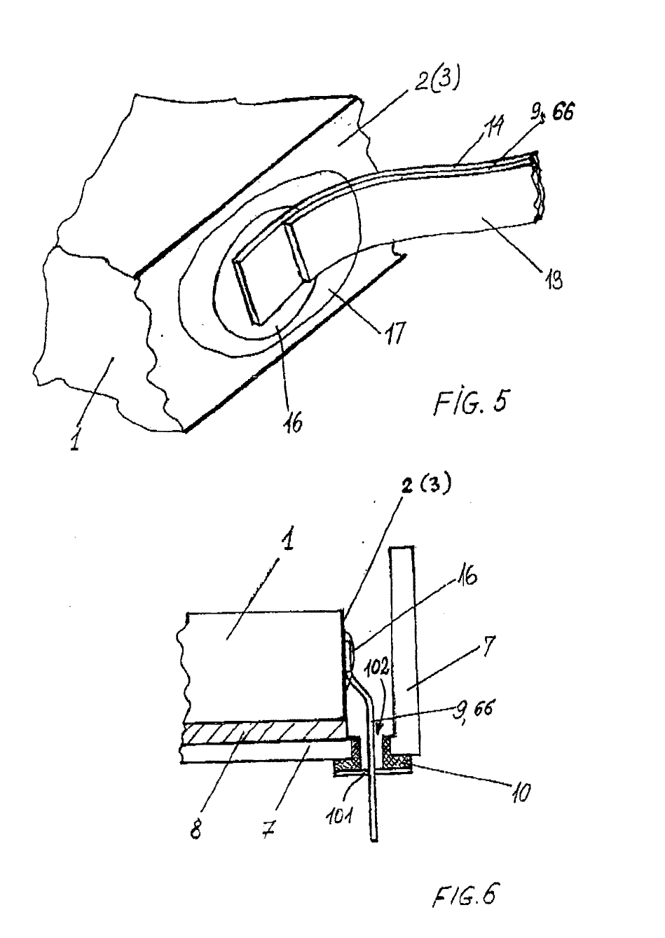

FIG. 5, cutouts of the contact point of the wire connection arranged on the main body through a protective layer;

FIG. 6, cutouts of a transformer arrangement in the region of the attachment points of the wire connection on the main body and in the cooling body.

The piezoelectric transformer presented in FIG. 1A has a main body 1, which is divided in a longitudinal direction into an input part 4, an output part 5, and an insulating region arranged between these parts. External electrodes 2, 2′ of the input part 4, as well as external electrodes 3, 3′ of the output part 5, are arranged on opposing side surfaces of the main body 1. The external electrodes can alternatively be arranged on the main surfaces of the main body as in the variant according to FIG. 1D.

The acoustic wave here propagates along the preferred direction of the main body 1. In the main body 1, the acoustic ground mode can be excited with a wavelength λ, which is twice as large as the length L of the main body 1. The nth-order harmonic can also be excited, whose wavelength equals 2 L/n, where n is a whole number, n≧2.

In the main body 1 there are, in one variant, internal electrodes, which are not shown here and which are connected to the external electrodes and which run perpendicular to the external electrodes and to the longitudinal direction of the main body. The acoustic wave, however, can also be excited between the external electrodes.

Each coupling element 8 extends along a line perpendicular to the longitudinal direction of the main body 1. The number and the position of the heat-conducting coupling elements 8 depend on the order of the harmonic. The piezoelectric transformer shown in FIG. 1A is especially suitable for the operation at the frequency of the second harmonic, wherein L=λ. Viewed in the longitudinal direction of the main body, the coupling elements 8 are each arranged approximately in the middle of the input part 4 and the output part 5. The average distance measured in the longitudinal direction between the coupling elements 8, i.e., between the support points of the main body, equals a half wavelength. The heat-conducting coupling elements are here each limited mainly to a region in which nodes appear.

In FIG. 1B, a transformer arrangement with the transformer according to FIG. 1A is shown, which is mounted on a cooling body 7 by means of two heat-conducting coupling elements 8 and thermally coupled to this cooling body.

The cooling body 7 is here made from an electrically conductive material. In its base there are openings in which electrically insulating inserts 10 are arranged with a positive fit, so that they are held tightly. In one insert 10, a metal pin 9 is held, which is provided as an electrical connection of the transformer arrangement. A preferably oscillation-damping wire connection 66 is attached or soldered on its first end to an external electrode 2, 2′, 3, 3′ of the transformer and on its second side to the metal pin 9.

The heat-conducting coupling elements 8 mainly contact only relatively narrow regions of the main body 1 in which nodes appear.

In FIG. 1C, a cross section of this arrangement through the input electrodes 2, 2′ perpendicular to the wave propagation direction is shown. On the upper side of the main body 1 there is a heat-conducting coupling element 8′.

In addition, a spring element 11 locked to side walls of the cooling body 7 is to be seen, which presses onto the composite of the main body 1 and the heat-conducting coupling elements 8, 8′ in the direction of the base plate of the cooling body 7 from above. Recesses are provided on the outer side of the side walls of the cooling body 7 for locking the spring element 11.

Two spring elements 11, 11′ are preferably and especially provided for a piezoelectric transformer designed for the second harmonic, as can be seen from FIG. 1F.

The spring element 11, 11′ preferably has good thermal conductivity. Thus, the main body 1 is also thermally coupled from above to the side walls of the cooler 7 via the upper heat-conducting coupling element 8′ and the heat-conducting spring element 11, 11′. The spring elements 11, 11′ are clamped between the side walls of the cooling body 7.

The cooling body 7 is electrically insulating in the variant according to FIG. 1D and can be, e.g., ceramic. Contact surfaces 6, 61 are arranged on the electrically insulating cooling body 7. These contact surfaces are each connected to a connection pin 9. However, they can be used themselves as electrical connections of the transformer arrangement. Here, a part of these contact surfaces can be arranged, for example, on the bottom side of the cooling body. In this case, the transformer arrangement is suitable for surface mounting, e.g., on an external circuit board.

The heat-conducting coupling elements 8, 8′ can extend as in FIG. 1D along a direction over the surface of the main body 1.

The heat-conducting coupling elements 8, 8′ are preferably electrically insulating in the variant according to FIG. 1C. In contrast, in the variant according to FIG. 1D, they are electrically conductive. The lower coupling element 8 here conductively connects the external electrodes 2, 3 of the piezoelectric transformer arranged on the bottom side of the main body 1 to a contact surface 6 arranged on the top side of the base plate of the cooler 7. The contact surface 6 is arranged partially on the top side of the base plate and partially on the outer side of the right side wall of the cooling body 7, wherein these regions of the contact surface 6 are conductively connected to each other by means of a contact hole. The contact surface 6 is conductively connected to the right connection pin 9.

The upper coupling element 8′ connects the main body 1 to the spring element 11, 11′ and to two side walls of the cooling body 7, wherein the upper coupling element 8′ is arranged partially on these side walls. The upper coupling element 8′ here conductively connects the external electrodes 2, 3′ of the piezoelectric transformer arranged on the upper side of the main body 1 to a contact surface 61 arranged on the outer side of the left side wall of the cooling body 7. The contact surface 61 is conductively connected to the left connection pin 9.

By means of the electrically conductive, heat-conducting coupling element 8, an electrical connection between the electrodes of the transformer and the connections 9 of the transformer arrangement can be realized. In this case, an electrically insulating cooling body is preferred.

The electrical connection between the external electrodes 2, 2′, 3, 3′ of the transformer and the contact surfaces of the cooling body by means of the conductive, heat-conducting coupling element 8 is possible especially if the external electrodes are arranged, as in FIGS. 1D and 3A, at least partially on the upper or lower side of the main body 1. However, also in the variant according to FIGS. 4A and 4C, parts arranged on the outer surface of the main body 1 in the external electrodes not shown in these figures can be conductively connected to contact surfaces arranged on the inside of the side wall of the cooling body 7 by means of the electrically conductive, heat-conducting coupling element 8 arranged in the longitudinal or radial direction.

If the electrical connection between the external electrodes of the transformer and the contact surfaces of the cooling body is realized by means of the electrically conductive, heat-conducting coupling elements 8, 8′, the elastically deformable coupling elements are especially advantageous, because they can damp the oscillations of the main body and can consequently reduce their transmission to the cooling body.

The heat-conducting coupling element can be composed, in one variant, from several layers. For example, a layer of the coupling element facing, e.g., the cooling body can be made from a hard material, such as ceramic or metal, which is coupled to the bottom side of the main body 1 by means of a heat-conducting, preferably oscillation-damping additional layer of the coupling element.

FIG. 1E corresponds to the cross section of the transformer arrangement according to FIG. 1F along line B-B.

In FIG. 1E, intermediate elements 12, 12′ are provided along a middle axis of the main body between the main body 1 and the side walls of the cooling body 7 running perpendicular to this direction. The intermediate elements 12, 12′ prevent the shifting of the main body 1 in the wave propagation direction, i.e., in the variant of FIG. 1E, in the longitudinal direction of the main body 1.

The intermediate elements 12, 12′ can be made from silicone rubber. Viewed in a longitudinal direction, they have a tapering cross section. The contact position between the intermediate element 12, 12′ and the (left or right) end face of the main body 1 is essentially a point contact.

In the variant according to FIGS. 1D and 1E, the main body 1 is mechanically coupled to the cooling body 7 only via the coupling elements 8, 8′ and the intermediate elements 12, 12′. In the variant according to Figure C, an additional mechanical coupling consists of the wire connections 66 and the connection pins 9. Therefore, it is advantageous to use flexible wire connections and to select, e.g., the length of these wire connections greater than the minimum distance between their two attachment points on the main body and on the connection pin.

In FIG. 1F it is to be seen that ventilation openings 74 are provided between side walls 72, 73 of the cooling body 7 arranged perpendicular to each other.

In FIG. 2, a housed piezoelectric transformer is shown with a disk-shaped main body 1.

The acoustic wave propagates in the variants according to FIGS. 2 and 3A in radial directions, which corresponds to a planar oscillation mode. The piezoelectric transformer is designed in these variants for the first harmonic or the ground wave, wherein the region in which antinodes appear corresponds to the outer surface of the main body. The region in which nodes appear extends along the vertical middle axis of the main body.

The heat-conducting coupling element 8 used as a support also in this variant for the main body 1 is arranged, in this case, in the middle, essentially in the node region.

The transformer has, in FIGS. 2, 3A, an input region, which has an annular cross section and which is connected to the external electrodes 2, 2′. The transformer further has an output region, which is arranged in the middle and which is enclosed on all sides by the input region and which has a round cross section and which is connected to the external electrodes 3, 2′. The input and output part of the transformer here have a common electrode 2′.

The wire connection 66 conductively connects the upper external electrode 3 of the transformer and the left connection pin 9. The attachment point of the wire connection 66 on the main body 1 or on the upper external electrode 3 is also arranged in the variant according to FIG. 2 in the region in which nodes appear.

The lower external electrode 2′ is conductively connected to the right connection pin 9 in FIG. 2 by means of another wire connection 66′.

In the variant according to FIG. 3A, the main body 1 is thermally coupled to the cooling body 7 as in FIG. 1C from below by means of a lower, heat-conducting coupling element 8 directly contacting the cooling body 7, and from above by means of an upper, heat-conducting coupling element 8′ via the spring element 11.

The cooling body 7 is here constructed as a cooling plate, in which openings 70 that are continuous from top to bottom are provided. On the cooling plate shown in FIGS. 3B and 3C there are contact surfaces 60, 61, 62, 63. All of the contact surfaces 60 to 63 are arranged on the top side of the cooling body 7. The arrangement of contact surfaces on its lower side also comes into consideration.

In FIG. 3D, the wiring of the transformer is shown according to FIG. 3A. The upper external electrode 2 is conductively connected to the contact surface 63 by means of a wire connection 66 that is not shown in FIG. 3A but is visible in FIG. 3C. The upper external electrode 3 is conductively connected to the contact surface 62 by means of the spring element 11 and a via hole arranged in the cooling body 7. The lower external electrode 2′ is conductively connected by means of the lower heat-conducting coupling element 8 to the contact surface 60 arranged underneath the main body 1. The contact surface 60 is here conductively connected to the contact surface 61 accessible from the outside and provided as an electrical connection of the transformer arrangement.

For the variant shown in FIG. 2, the description of the variant according to FIGS. 1B, 1C applies and for the variant shown in FIG. 3A, the description of the variant according to FIG. 1D applies up to the already explained differences. In the transformer arrangement shown in FIGS. 2, 3A, alternatively, a transformer with a right parallelepiped-shaped main body can be used.

It is advantageous to form a transformer provided as a thickness oscillator with a cylindrical or disk-shaped main body.

In FIG. 4A, a variant is shown in which, in contrast to the previously explained embodiments, a thickness oscillator that is designed for a ground wave is realized in the main body 1 of the transformer. The oscillations of the main body are realized in this case in the vertical direction, i.e., the wave propagation direction in this case is also directed vertically. The maximum oscillation amplitudes or regions in which antinodes appear correspond in FIG. 4A to the bottom side and the top side of the main body 1. The region in which nodes appear is arranged in a lateral plane, which passes approximately through the middle of the main body. In the region of this plane there are heat-conducting coupling elements 8 that hold the main body 1 between the side walls of the cooling body 7. The coupling elements made from an elastically deformable material are advantageous for fixing the main body 1.

The main body 1 is supported from below by an intermediate element 12, which was already explained above and which is here arranged between the bottom side of the main body 1 and the top side of the base plate of the cooling body 7. The intermediate element 12 is here arranged along a vertical middle axis of the main body 1.

A spring element that touches the main body 1 from above preferably only in a region with a small surface can also be provided in the variant according to FIG. 4A. Otherwise, the electrical connections between the external electrodes of the transformer and the electrical connections of the transformer arrangement can be realized as in the already explained variants.

The main body in the variant according to FIG. 4A can have a right parallelepiped shape and also a disk shape as shown in FIG. 4B.

The cooling body 7 in variants according to FIGS. 4B and 4C has an outer cylinder 701. In the variant according to FIG. 4C, an inner cylinder 702 is also provided. The inner and outer cylinder, however, can be replaced with a tube with an arbitrary cross section, wherein the cross-sectional shape of the tube is preferably adapted to the outer cross section of the main body.

In particular, the inner cross section of the housing or its inner outline is preferably adapted to the outer cross section or the outer outline of the main body, wherein, e.g., for a disk-shaped main body a cylindrical main body is used and for a right parallelepiped main body a rectangular housing is used.

In FIG. 4B, the disk-shaped main body 1 is biased by means of the heat-conducting, preferably elastically deformable coupling element 8 in the cup-shaped cooling body 7. The coupling elements 8 here thermally couple the outer surface of the main body 1 to the inner surface of the outer cylinder 701.

In FIG. 4B, every two heat-conducting coupling elements 8 are arranged in two radial directions running transverse or perpendicular to each other. In the case of a thickness oscillator, it is also possible to use an annular heat-conducting coupling element arranged in the node plane between the outer surface of the main body 1 and the inner surface of the cooling body 7.

In FIG. 4C, a transformer arrangement is shown with a piezoelectric transformer, which has an annular cross section and which is biased by means of the heat-conducting, preferably elastically deformable coupling elements 8, 8′ between the outer cylinder 701 and the inner cylinder 702 of the cooling body 7. In addition to the elements shown in FIG. 4B, here, additional heat-conducting coupling elements 8′, which thermally couple the surface of the main body 1 facing inward to the inner cylinder 702, are provided between the inner surface of the cooling body 7 and the inner surface of the main body 1. Also here, four coupling elements 8 and/or four coupling elements 8′ can be replaced with a single annular coupling element.

The cooling body 7 in FIG. 4C has the shape of a trough, wherein its outer cylinder and its inner cylinder are connected to each other by an annular base. In the middle of the trough or the inner cylinder there is a hole 700.

FIG. 5 shows the contact position 16 of the wire connection 66 to an external electrode of the piezoelectric transformer, e.g., the external electrode 2 or 3. The wire connection 66 is a flat wire with a metal band 14 and a plastic layer 13. The plastic layer 13 provides that mechanical oscillations in the wire connection 66 are damped to a high degree and thus the transmission of the acoustic oscillations from the main body out of the cooling body is essentially prevented. This relieves stress on the two attachment points of the wire connection 66 on the main body 1 and in the housing or on an electrical connection arranged in the housing.

The metal band 14 is soldered to the external electrode. Thus, one end of the wire connection 66 is fixed to the main body 1. The second end of the wire connection 66 can be fixed, e.g., as in the variant according to FIG. 6. A preferably electrically insulating protective layer 17 is deposited on the contact position 16. The protective layer 17 can be a compound material, e.g., made from epoxy resin or a cured adhesive material. A protective layer 17 made from rubber is also suitable. The protective layer 17 can be formed in one variant by a heat-shrinkable sleeve.

The protective layer 17 also lies on a section of the wire connection 66 outside of the attachment position and presses it against the main body 1. This realizes mechanical stress relief for the contact position 16.

FIG. 6 shows a variant in which the transformer arrangement has elastically deformable electrical connections 9, which are fixed directly to the external electrodes 2, 2′, 3, 3′ of the main body 1 and which replace a wire connection 66 shown in FIGS. 1C, 2. Therefore, because elastically deformable electrical connections 9 can oscillate, its attachment point on the main body is mechanically relieved of stress.

The connections 9 are preferably constructed as a flat band; see also FIG. 5. They are guided through the cooling body 7. The insert 10 already shown in FIG. 1C is here constructed with an opening whose cross-sectional size exceeds the cross-sectional size of the connection 9, so that the connection 9 can oscillate without contacting the insert 10.

A metal disk 101 in which an opening is formed is attached to the bottom side of the insert 10. The cross-sectional size of this opening is essentially adapted to the cross-sectional size of the connection 9—in one variant with a positive fit. The connection 9 can be rigidly connected, e.g., by means of a solder mass, to the metal disk 101. The lower end of the connection 9 can be bent.

The specified transformer arrangement with a piezoelectric transformer is not limited to the variants shown in the figures, specifically, it is not limited to the number of shown elements and the special shaping or material specifications. The advantageous solutions explained in the figures, particularly with reference to mechanical decoupling of a transformer and a carrier, can be used in combination with other constructions of a piezoelectric transformer and/or a carrier not shown here.

### LIST OF REFERENCE SYMBOLS

1 Main body of the piezoelectric transformer
10 Insulating insert
101 Conductive element
102 Recess in insulating insert
11, 11′ Spring element
12, 12′ Intermediate element for holding the main body in the cooling body
14 Metal layer
15 Plastic layer
16 Connection position between the external electrodes 2, 3 of the main body 4 and the wire connection 66
17 Protective layer
2, 2′ External electrodes of the input part
3, 3′ External electrodes of the output part
4 Input part of the piezoelectric transformer
5 Output part of the piezoelectric transformer
6, 60, 61, 62, 63 Contact surfaces on the cooling body
66 Wire connection
7 Cooling body
70 Openings provided in the cooling body 7 for holding spring clips of the spring element 11
700 Inner hole of the cooling body 7
701 Outer tube of the cooling body 7
702 Inner tube of the cooling body 7
72, 73 Side walls 72, 73 of the cooling body 7
74 Ventilation openings
8, 8′ Heat-conducting coupling element
9 External connection formed as a pin for the transformer arrangement

1. A transformer arrangement, comprising:
a piezoelectric transformer comprising:
a cooling body; and
a main body on the cooling body and thermally coupled to the cooling body by at least one heat-conducting coupling element.

2. The transformer arrangement of claim 1, wherein a length of the at least one heat-conducting coupling element in a direction of propagation of an acoustic wave excited in the main body is smaller than a length of the main body in the direction of propagation of the acoustic wave in the main body.

3. The transformer arrangement of claim 1, wherein an area of a contact surface between the coupling element and the main body is less than an area of a boundary surface of the main body that includes the contact surface.

4. The transformer arrangement of claim 1, wherein the cooling body forms at least a portion of a housing in which the main body is arranged.

5. The transformer arrangement of of claim 1, wherein the cooling body includes ribs.

6. The transformer arrangement of claim 2, wherein the at least one heat-conducting coupling element is elongated in a direction transverse to the direction of propagation of the acoustic wave in the main body.

7. The transformer arrangement of claim 1, wherein the at least one heat-conducting coupling element comprises several heat-conducting coupling elements spaced apart to form an air gap between the main body and the cooling body.

8. The transformer arrangement of claim 1, wherein the at least one heat-conducting coupling element is in a region of a surface of the main body in which nodes of an acoustic wave excited in the main body appear.

9. The transformer arrangement of claim 1, wherein a length of the coupling element in a wave propagation direction is at most about 30% of a length of the main body in the direction of the wave propagation.

10. The transformer arrangement of claim 7, wherein a length of the air gap in a direction of the wave propagation is at least about 50% of a length of the main body in the direction of the wave propagation.

11. The transformer arrangement of claim 1, wherein a total surface area of the cooling body is greater than the a total surface area of the main body.

12. The transformer arrangement of claim 1, wherein the at least one heat-conducting coupling element is elastically deformable.

13. The transformer arrangement of claim 1, wherein the at least one heat-conducting coupling element comprises a paste.

14. The transformer arrangement of claim 1, wherein the at least one heat-conducting coupling element is electrically conductive.

15. The transformer arrangement of claim 14, wherein the at least one heat-conducting coupling element conductively connects an external electrode on the main body and a contact layer on the cooling body.

16. The transformer arrangement of claim 1, wherein the at least one heat-conducting coupling element comprises a first heat conducting element on a first side of the main body and a second heat conducting element on an opposing side of the main body.

17. The transformer arrangement of claim 1, wherein the at least one a heat-conducting coupling element is on an upper side of the main body, and the transformer arrangement further comprises:
a spring element biased on the cooling body and configured to press against the heat-conducting coupling element and thermally connect the heat-conducting coupling element to the cooling body.

18. The transformer arrangement of claim 17, wherein the spring element conductively connects the heat-conducting coupling element to a contact surface on the cooling body.

19. The transformer arrangement of claim 1, further comprising an intermediate element configured to hold the main body in the cooling body the intermediate element being between a side of the main body and the cooling body.

20. The transformer arrangement of claim 19, wherein the intermediate element is between a side of the main body arranged parallel to the wave front and the cooling body.

21. The transformer arrangement of claim 1, wherein the at least one heat-conducting coupling element comprises a first heat-conducting coupling element on a first side of the main body and a second heat-conducting coupling element on an opposing side of the main body.

22. The transformer arrangement of claim 21, wherein the main body is clamped between the first and second heat-conducting coupling elements contacting the cooling body.

23. The transformer arrangement of claim 21, wherein:
the cooling body includes an inner tube and an outer tube, and
the main body has a annular shape and is clamped between the inner tube and the outer tube by the coupling elements.

24. The transformer arrangement of claim 1, wherein the cooling body comprises an electrically insulating material with good thermal conductivity.

25. The transformer arrangement of claim 1, wherein the cooling body comprises a ceramic material.

26. The transformer arrangement of claim 24, further comprising connections including contact surfaces on the surface of the cooling body.

27. The transformer arrangement of claim 1, wherein the cooling body comprises at least one of a metal main body and a metal plate.

28. The transformer arrangement of claim 27, further comprising at least one pin-shaped electrical connection in the cooling body.

29. The transformer arrangement of claim 28, wherein the at least one pin-shaped electrical connection is conductively connected by a wire connection to an external electrode on a surface of the main body.

30. The transformer arrangement of claim 29, wherein the wire connection is configured to dampen the transmission of mechanical oscillations of the main body to the cooling body.

31. The transformer arrangement of claim 29, wherein a length of the wire connection is greater than a distance between the external electrode and the at least one pin-shaped electrical connection of the cooling body.

32. The transformer arrangement of claim 29, wherein the wire connection includes at least one metal layer and at least one plastic layer.

33. The transformer arrangement of claim 1, wherein the at least one heat-conducting coupling element forms an air gap between the main body and the cooling body.

34. The transformer arrangement of claim 1, wherein electrical connections of the transformer are guided through the cooling body.
